(19) United States
(12) Patent Application Publication
(10) Pub. No.: US 2010/0132783 A1
(43) Pub. Date: Jun. 3, 2010

(54) TRANSPARENT CONDUCTIVE FILM WITH HIGH SURFACE ROUGHNESS FORMED BY A REACTIVE SPUTTER DEPOSITION

(75) Inventors: Hien-Minh Huu Le, San Jose, CA (US); David Tanner, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/326,583

(22) Filed: Dec. 2, 2008

(51) Int. Cl. H01L 31/0288; C23C 14/34

(52) U.S. Cl. 136/256; 204/192.1; 136/265

(57) ABSTRACT

Methods for sputter depositing a transparent conductive layer are provided in the present invention. The transparent conductive layer may be utilized as a contact layer on a substrate or a back reflector in a photovoltaic device. In one embodiment, the method includes supplying a gas mixture into a processing chamber, sputtering source material from a target disposed in the processing chamber, wherein the target has dopants doped into a base material, wherein the dopants are selected from a group consisting of boron containing materials, titanium containing materials, tantalum containing materials, tungsten containing materials, alloys thereof, or combinations thereof, and reacting the sputtered material with the gas mixture to deposit a transparent conductive layer on a substrate disposed in the processing chamber.

### BACKGROUND OF THE DISCLOSURE

1. Field of the Invention

The present invention relates to methods and apparatus for depositing a transparent conductive film, more specifically, for reactively sputtering depositing a transparent conductive film with high surface roughness for photovoltaic devices.

2. Description of the Background Art

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with specific frames and connectors.

Several types of PV devices including microcrystalline silicon film (μc-Si), amorphous silicon film (a-Si), polycrystalline silicon film (poly-Si) and the like are being utilized to form PV devices. A transparent conductive film or a transparent conductive oxide (TCO) film is often used as a top surface electrode, often referred as back reflector, disposed on the top of the PV solar cells. Alternatively, the transparent conductive film is also used between the substrate and a photoelectric conversion unit. The transparent conductive film must have high optical transmittance in the visible or higher wavelength region to facilitate transmitting sunlight into the solar cells without adversely absorbing or reflecting light energy. Also, the transparent conductive film is often desired to have certain degree of textured or roughness. Conventionally, a wet clean process is typically performed on a transparent conductive layer to increase the roughness of the transparent conductive surface layer. However, an extra wet etching process often increases manufacturing cost and increases the overall cycle time of the manufacturing process. Additionally, after a number of wet etching processes have performed, the wet etching solution often has impurities or becomes contaminated. Subsequently processed transparent conductive layers may be contaminated by the etching solution, thereby adversely affecting film quality and properties of the transparent conductive layer.

Therefore, there is a need for an improved method for depositing a transparent conductive film with high surface roughness for PV cells.

### SUMMARY OF THE INVENTION

Methods for sputter deposition of a transparent conductive layer with high surface roughness suitable for use in PV cells are provided in the present invention. In one embodiment, a method includes supplying a gas mixture into a processing chamber, sputtering source material from a target disposed in the processing chamber, wherein the target has dopants doped into a base material, wherein the dopants are selected from a group consisting of boron containing materials, titanium containing materials, tantalum containing materials, tungsten containing materials, alloys thereof, or combinations thereof, and reacting the sputtered material with the gas mixture to deposit a transparent conductive layer on a substrate disposed in the processing chamber.

In another embodiment, a method for sputter deposition of a transparent conductive layer includes providing a substrate in a processing chamber, forming a first transparent conductive layer on the substrate, and forming a second transparent conductive layer on the first transparent conductive layer, wherein the second transparent conductive layer comprising dopants doped into a base material, wherein the dopants is selected from a group consisting of boron containing materials, titanium containing materials, tantalum containing materials, tungsten containing materials, alloys thereof, or combinations thereof.

In yet another embodiment, a film stack for a PV solar cell includes a substrate having a first transparent conductive layer disposed thereon, and a second transparent conductive layer deposited on the first transparent conductive layer, wherein the second transparent conductive layer, the second transparent conductive layer having a surface roughness greater than about 30 nm, the second transparent conductive layer having dopants doped into a base material, wherein the dopants are selected from a group consisting of boron containing materials, titanium containing materials, tantalum containing materials, tungsten containing materials, alloys thereof, or combinations thereof.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber in accordance with the invention;

FIG. 2 depicts an exemplary cross sectional view of a silicon-based thin film PV solar cell in accordance with one embodiment of the present invention;

FIG. 3 depicts a process flow diagram for depositing a transparent conductive layer in accordance with one embodiment of the present invention;

FIG. 4 depicts a process flow diagram for depositing a transparent conductive layer in accordance with one embodiment of the present invention; and

FIGS. 5A-5B depict an exemplary cross sectional view of a tandem type PV solar cell in accordance with another embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for sputter depositing a transparent conductive layer having a high surface roughness suitable for use in the fabrication of solar cells. In one embodiment, the surface roughness of the transparent conductive layer may be obtained by selecting certain dopants provided in the transparent conductive layer. Dopants formed in the transparent conductive layer may have a grain size different than that of the base materials in the transparent conductive layer, thereby creating a rough surface topography on the transparent conductive layer.

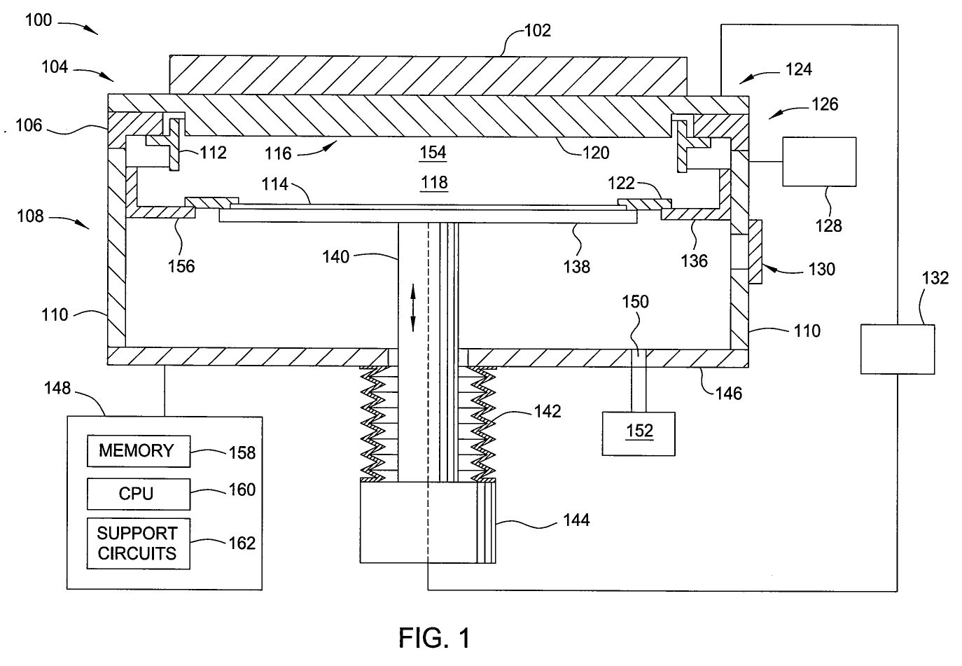

FIG. 1 illustrates an exemplary reactive sputter process chamber 100 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufacturers, may be adapted to practice the present invention.

The process chamber 100 includes a chamber body 108 having a processing volume 118 defined therein. The chamber body 108 has sidewalls 110 and a bottom 146. A chamber lid assembly 104 is mounted on the top of the chamber body 108. The chamber body 108 may be fabricated from aluminum or other suitable materials. The dimensions of the chamber body 108 and related components of the process chamber 100 are not limited and generally are proportionally larger than the size of the substrate 114 to be processed. Any suitable substrate size may be processed. Examples of suitable substrate sizes include substrate having a surface area of about 2000 centimeter square or more, such as about 4000 centimeter square or more, for example about 10000 centimeter square or more. In one embodiment, a substrate having a surface area of about 50000 centimeter square or more or more may be processed.

A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), H₂, N₂O, NO₂ and H₂O, among others.

A pumping port 150 is formed through the bottom 146 of the chamber body 108. A pumping device 152 is coupled to the process volume 118 to evacuate and control the pressure therein. In one embodiment, the pressure level of the process chamber 100 may be maintained at about 1 Torr or less. In another embodiment, the pressure level of the process chamber 100 may be maintained at about 10⁻³ Torr or less. In yet another embodiment, the pressure level of the process chamber 100 may be maintained at about 10⁻⁵ Torr to about 10⁻⁷ Torr. In another embodiment, the pressure level of the process chamber 100 may be maintained at about 10⁻⁷ Torr or less.

The lid assembly 104 generally includes a target 120 and a ground shield assembly 126 coupled thereto. The target 120 provides a material source that can be sputtered and deposited onto the surface of the substrate 114 during a PVD process. The target 120 or target plate may be fabricated from a material utilized for deposition species. A high voltage power supply, such as a power source 132, is connected to the target 120 to facilitate sputtering materials from the target 120. As the materials utilized to fabricate the target is highly associated with the materials to be deposited on the substrate, selection of the target material may significantly influence the film properties formed on the substrate. In one embodiment, the target 120 may be fabricated from a material containing zinc (Zn) metal. In another embodiment, the target 120 may be fabricated from materials including metallic zinc (Zn) target, zinc alloy, zinc and the like. Different dopant materials, such as boron containing materials, titanium containing materials, tantalum containing materials, tungsten containing materials, aluminum containing materials, and the like, may be doped into a zinc containing base material to form the target with a desired dopant concentration. In one embodiment the dopant materials include boron containing materials, titanium containing materials, tantalum containing materials, tungsten containing materials, alloys thereof, combinations thereof and the like. In one embodiment, the target 120 may be fabricated from a zinc oxide material having dopants, such as, titanium oxide, tantalum oxide, tungsten oxide, aluminum oxide, boron oxide and the like doped therein. In one embodiment, the dopant concentration formed in the zinc containing material is controlled about less than 10 percent by weight.

In one embodiment, the dopants doped in the base materials formed in the target is selected to have different grain sizes, as compared to the grain size of the base material, to create surface roughness on the deposited transparent conductive layer. The grain size of the dopants may be selected to have a relatively larger grain size or a relatively smaller size, as compared to the grain size of the base material. For example, in the embodiment wherein the base material of the target 120 is fabricated from zinc (e.g., a molecular weight about 65), boron element (e.g. a molecular weight about 10) having a grain size relatively smaller than the grain size of zinc may be utilized to create a non-uniform grain surface when depositing on the substrate surface. In contrast, tungsten and titanium elements have comparatively larger grain sizes than zinc element. When utilizing tungsten and titanium elements as dopants doped into the zinc containing material, the contrast in grain size between the grains of tungsten or titanium elements and the zinc element may also create a non-uniform grain surface. Accordingly, by depositing a film having contrasting grain sizes between the dopants and the base material, a rough surface of a transparent conductive layer may be formed by an uneven arrangement and distribution of grain sizes on the deposited layer. In one embodiment, the dopant concentration selected to be doped into the base material fabricating the target needs to not only create a desired surface roughness, but also to maintain film transparency and conductivity provide good light transmittance. In one embodiment, the concentration of the dopant element formed in the zinc containing target 120 is about less than 10 percent by weight. In another embodiment, the concentration of the dopant element formed in the zinc containing target 120 is between about less than 5 percent by weight. In yet another embodiment, the concentration of the dopant element formed in the zinc containing target 120 is between about less than 3 percent, such as less than 2 percent by weight, for example about 0.25 percent by weight.

The target 120 generally includes a peripheral portion 124 and a central portion 116. The peripheral portion 124 is disposed over the sidewalls 110 of the chamber 100. The central portion 116 of the target 120 may have a curvature surface slightly extending towards the surface of the substrate 114 disposed on a substrate support 138. The spacing between the target 120 and the substrate support 138 is maintained between about 50 mm and about 150 mm. It is noted that the dimension, shape, materials, configuration and diameter of the target 120 may be varied for specific process or substrate requirements. In one embodiment, the target 120 may further include a backing plate having a central portion bonded and/or fabricated from a material desired to be sputtered onto the substrate surface. The target 120 may also include adjacent tiles or segment materials that together form the target.

Optionally, the lid assembly 104 may further comprise a magnetron assembly 102 mounted above the target 120 which enhances efficient sputtering materials from the target 120 during processing. Examples of the magnetron assembly 102 include a linear magnetron, a serpentine magnetron, a spiral magnetron, a double-digitated magnetron, a rectangularized spiral magnetron, among others.

The ground shield assembly 126 of the lid assembly 104 includes a ground frame 106 and a ground shield 112. The ground shield assembly 126 may also include other chamber shield member, target shield member, dark space shield, dark space shield frame. The ground shield 112 is coupled to the peripheral portion 124 by the ground frame 106 defining an upper processing region 154 below the central portion of the target 120 in the process volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110. In one embodiment, the ground shield 112 may be formed by one or more work-piece fragments and/or a number of these pieces bonding by processes such as welding, gluing, high pressure compression, etc.

A shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal therebetween, thereby maintaining vacuum integrity of the chamber processing volume 118.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate transfer port 130, the shadow frame 122 is set back on the chamber shield 136. Lift pins (not shown) are selectively moved through the substrate support 138 to list the substrate 114 above the substrate support 138 to facilitate access to the substrate 114 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the target 120. The CPU 160 may be any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, the material is sputtered from the target 120 and deposited on the surface of the substrate 114. The target 120 and the substrate support 138 are biased relative to each other by the power source 132 to maintain a plasma formed from the process gases supplied by the gas source 128. The ions from the plasma are accelerated toward and strike the target 120, causing target material to be dislodged from the target 120. The dislodged target material and process gases forms a layer on the substrate 114 with desired compositions.

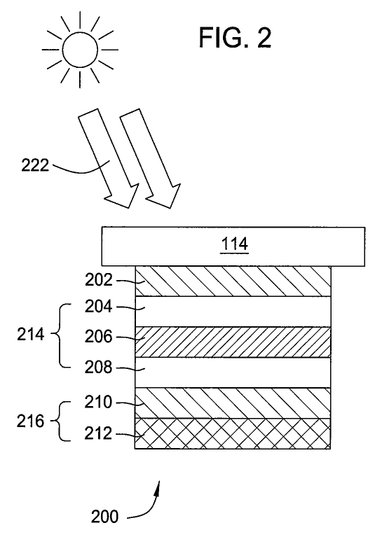

FIG. 2 depicts an exemplary cross sectional view of an amorphous silicon-based thin film PV solar cell 200 in accordance with one embodiment of the present invention. The amorphous silicon-based thin film PV solar cell 200 includes a substrate 114. The substrate 114 may be thin sheet of metal, plastic, organic material, silicon, glass, quartz, or polymer, or other suitable material. The substrate 114 may have a surface area greater than about 1 square meters, such as greater than about 2 square meters. Alternatively, the thin film PV solar cell 200 may also be fabricated as crystalline, microcrystalline or other type of silicon-based thin films as needed.

A photoelectric conversion unit 214 is formed on a transparent conductive layer 202 disposed on the substrate 114. The photoelectric conversion unit 214 includes a p-type semiconductor layer 204, a n-type semiconductor layer 208, and an intrinsic type (i-type) semiconductor layer 206 sandwiched therebetween as a photoelectric conversion layer. An optional dielectric layer (not shown) may be disposed between the substrate 114 and the transparent conductive layer 202, between the transparent conductive layer 202 and the p-type semiconductor layer, or between the intrinsic type (i-type) semiconductor layer 206 and the n-type semiconductor layer 208 as needed. In one embodiment, the optional dielectric layer may be a silicon layer including amorphous or poly silicon layer, SiON, SiN, SiC, SiOC, silicon oxide (SiO₂) layer, doped silicon layer, or any suitable silicon containing layer.

The p-type and n-type semiconductor layers 204, 208 may be silicon based materials doped by an element selected either from Group III or V. A Group III element doped silicon film is referred to as a p-type silicon film, while a Group V element doped silicon film is referred to as a n-type silicon film. In one embodiment, the n-type semiconductor layer 208 may be a phosphorus doped silicon film and the p-type semiconductor layer 204 may be a boron doped silicon film. The doped silicon films 204, 208 include an amorphous silicon film (a-Si), a polycrystalline film (poly-Si), and a microcrystalline film (pc-Si) with a thickness between around 5 nm and about 50 nm. Alternatively, the doped element in semiconductor layers 204, 208 may be selected to meet device requirements of the PV solar cell 200. The n-type and p-type semiconductor layers 204, 208 may be deposited by a CVD process or other suitable deposition process.

The i-type semiconductor layer 206 is a non-doped type silicon based film. The i-type semiconductor layer 206 may be deposited under process condition controlled to provide film properties having improved photoelectric conversion efficiency. In one embodiment, the i-type semiconductor layer 206 may be fabricated from i-type polycrystalline silicon (poly-Si), i-type microcrystalline silicon film (pc-Si), amorphous silicon (a-Si), or hydrogenated amorphous silicon (a-Si).

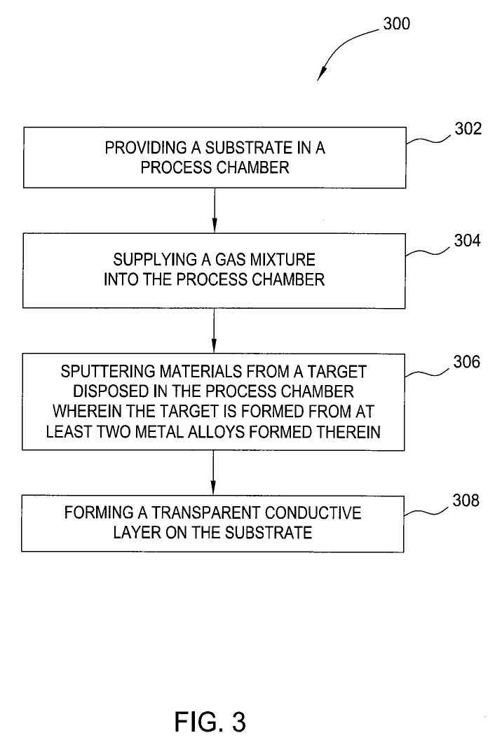

After the photoelectric conversion unit 214 is formed on the transparent conductive layer 202, a back reflector 216 is disposed on the photoelectric conversion unit 214. In one embodiment, the back reflector 216 may be formed by a stacked film that includes a transparent conductive layer 210 and a conductive layer 212. The conductive layer 212 may be at least one of Ti, Cr, Al, Ag, Au, Cu, Pt, or their alloys. The transparent conductive layer 210 may be fabricated from a material similar to the transparent conductive layer 202 formed on the substrate 114. The transparent conductive layers 202, 210 may be fabricated from a selected group consisting of tin oxide (SnO₂), indium tin oxide (ITO), zinc oxide (ZnO), or combinations thereof. In one exemplary embodiment, the transparent conductive layers 202, 210 may be fabricated from a ZnO layer having a desired Al₂O₃ dopant concentration formed in the ZnO layer. The method of how to form the ZnO/Al₂O₃ layer will be described in process 300 with reference to FIG. 3.

In embodiments depicted in FIG. 2, at least one of the transparent conductive layers 202, 210 is fabricated by reactive sputter deposition process according to the present invention. The sputter deposition process of transparent conductive layers 202, 210 may be performed in the processing chamber 100, as described in FIG. 1. Alternatively, the PV solar cell 200 may be fabricated or deposited in a reversed order. For example, the substrate 114 may be disposed over the back reflector 216.

FIG. 3 depicts a flow diagram of one embodiment of a sputtering deposition process 300 for depositing a transparent conductive layer, such as transparent conductive layers 202, 210, on the substrate 114 or on the photoelectric conversion unit 214. The process 300 may be stored in the memory 158 as instructions that when executed by the controller 148, cause the process 300 to be performed in the process chamber 100. In embodiment depicted in FIG. 3, the process 300 is performed in a Thin Film Solar PVD system from Applied Materials, Inc.

The process 300 begins at step 302 by providing a substrate into a sputter process chamber for deposition a transparent conductive layer on the substrate. In one embodiment, the transparent conductive layer may be deposited as the transparent conductive layer 202 on the substrate 114. In another embodiment, the transparent conductive layer may be deposited as the transparent conductive layer on the photoelectric conversion unit 214 as the back reflector 216.

At step 304, a process gas mixture is supplied into the sputter process chamber. The process gas mixture supplied in the sputter process chamber assists bombarding the source material from the target 120 and reacts with the sputtered material to form the desired transparent conductive layer on the substrate surface. In one embodiment, the gas mixture may include reactive gas, non-reactive gas, inert gas, and the like. Examples of non-reactive gas include, but not limited to, inert gas, such as Ar, He, Xe, and Kr, or other suitable gases. Examples of reactive gas include, but not limited to, O₂, N₂, N₂O, NO₂, H₂, NH₃, H₂O, among others.

In one embodiment, the argon (Ar) gas supplied into the sputter process chamber assists bombarding the target materials from the target surface. The sputtered materials from the target react with the reactive gas in the sputter process chamber, thereby forming a transparent conductive layer having desired film properties on the substrate.

In one particular embodiment depicted here, the process gas mixture supplied into the sputter process chamber includes at least one of Ar, O₂ or H₂. In one embodiment, the O₂ gas may be supplied at a flow rate between about 0 sccm and about 100 sccm, such as between about 5 sccm and about 30 sccm. The Ar gas may be supplied into the processing chamber 100 at a flow rate between about 100 sccm and between 500 sccm. The H₂ gas may be supplied into the processing chamber 100 at a flow rate between about 0 sccm and between 100 sccm, such as between about 5 sccm and about 30 sccm. Alternatively, O₂ gas flow may be controlled at a flow rate per total flow rate between about 1 percent and about 10 percent. H₂ gas flow may be controlled at a flow rate per total flow rate between about 1 percent and about 10 percent.

At step 306, a RF power is supplied to the target 120 to sputter the source material from the target 120 to react with the gas mixture supplied at step 304. As a high voltage power is supplied to the target 120, the metal material is sputtered from the target 120 in form of metallic ions, such as Zn⁺, Zn²⁺, Al³⁺, Ti²⁺, B³⁺, if any, and the like. The bias power applied between the target 120 and the substrate support 138 maintains a plasma formed from the gas mixture in the process chamber 100. The ions from the gas mixture in the plasma bombard and sputter off material from the target 120. The ions from the reactive gases react with the growing sputtered film to form a layer with desired composition on the substrate 114.

In one embodiment, the target 120 has different dopants doped therein. Selection of the dopants incorporated into the target may be varied to meet different process requirements. In the embodiment wherein a high surface roughness of the resultant deposited transparent conductive is desired, dopants that have relatively large grain size or a relatively smaller grain size compared with the grain size of the base material of the target. For example, an element having a smaller grain size or a larger grain size relative to the grain size of the base material comprising the target may be doped into the base material. The dopants formed in the base material provide grains with different sizes sputtered from the target, thereby creating a non-uniform distribution of grain sizes across the substrate surface, creating an uneven surface on the substrate. The grain size distribution across the substrate surface creates an uneven surface topography, thereby increasing the surface roughness of the deposited transparent conductive layer. In one embodiment, the dopants that may be doped in the target include boron containing materials, titanium containing materials, tantalum containing materials, tungsten containing materials, aluminum containing materials, alloys thereof, combinations thereof, and the like. The base material comprising the target may include zinc, zinc alloy, zinc containing materials, zinc oxide and the like. In an exemplary embodiment, titanium oxide or boron oxide may be doped into a zinc oxide based target. The ratio titanium oxide or boron oxide to the zinc oxide based target is about less than 10 percent by weight, such as about less than 5 percent by weight, for example, about 2 percent by weight, such as about 0.25 percent by weight.

In one embodiment, a RF power may be supplied to the target between about 1000 Watts and about 60000 Watts. Alternatively, the RF power maybe controlled by supplying a RF power density may be supplied between about 0.15 Watts per centimeter square and about 15 Watts per centimeter square, for example, about 4 Watts per centimeter square and about 8 Watts per centimeter square. Alternatively, the DC power may be supplied between about 0.15 Watts per centimeter square and about 15 Watts per centimeter square, for example, about 4 Watts per centimeter square and about 8 Watts per centimeter square.

Several process parameters may be regulated at step 304 and 306. In one embodiment, a pressure of the gas mixture in the process chamber 100 is regulated between about 2 mTorr and about 10 mTorr. The substrate temperature may be maintained between about 25 degrees Celsius and about 100 degrees Celsius. The processing time may be processed at a predetermined processing period or after a desired thickness of the layer is deposited on the substrate. In one embodiment, the process time may be processed at between about 30 seconds and about 400 seconds. In one embodiment, the thickness of the transparent conductive layer is between about 5000 Å and about 10000 Å. In the embodiment wherein a substrate with different dimension is desired to be processed, process temperature, pressure and spacing configured in a process chamber with different dimension do not change in accordance with a change in substrate and/or chamber size.

At step 308, as the ions dissociated from the gas mixture react with the material sputtered from the target 120, a transparent conductive layer with desired composition is formed on the substrate surface. It is believed that the transparent conductive layer having a desired amount of dopant formed in the base material made in the target 120 can efficiently create an uneven surface topography, thereby increasing the surface roughness of the formed transparent conductive layer. In selecting dopants for the transparent conductive layer, the dopants should not only create the desired surface roughness, but also maintain film transparency, conductivity so as to maintain high current conversion efficiency to the photoelectric conversion unit. By selecting dopant from a group consisting of boron containing materials, titanium containing materials, tantalum containing materials, tungsten containing materials, aluminum containing materials, alloys thereof, or combinations thereof, a transparent conductive layer having high surface roughness as well as high film transmittance may be obtained.

In one embodiment, the transparent conductive layer has a boron oxide or titanium oxide dopant concentration between about 0.25 percent by weight and about 5 percent by weight in a ZnO based material, such as between about 0.25 percent by weight and about 3 percent by weight in a ZnO based material. The transparent conductive layer is desired to have a surface roughness greater than 30 nm, such as between about 30 and about 80.

In operation, the incident light 222 provided by the environment is supplied to the PV solar cell 200. The photoelectric conversion unit 214 in the PV solar cell 200 absorbs the light energy and converts the light energy into electrical energy by operation of the p-i-n junctions formed in the photoelectric conversion unit 214, thereby generating electricity or energy.

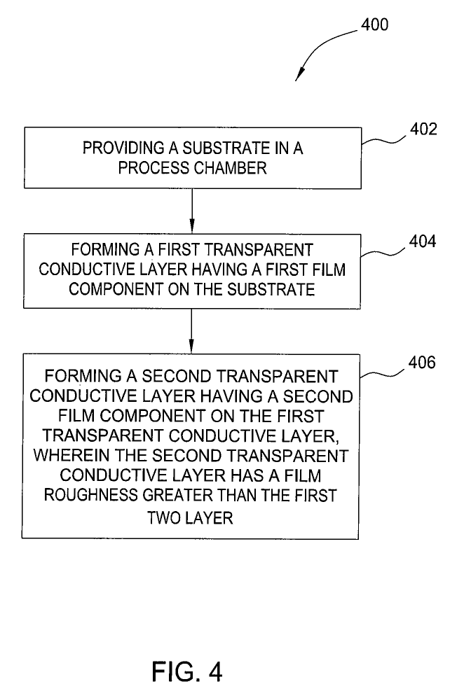

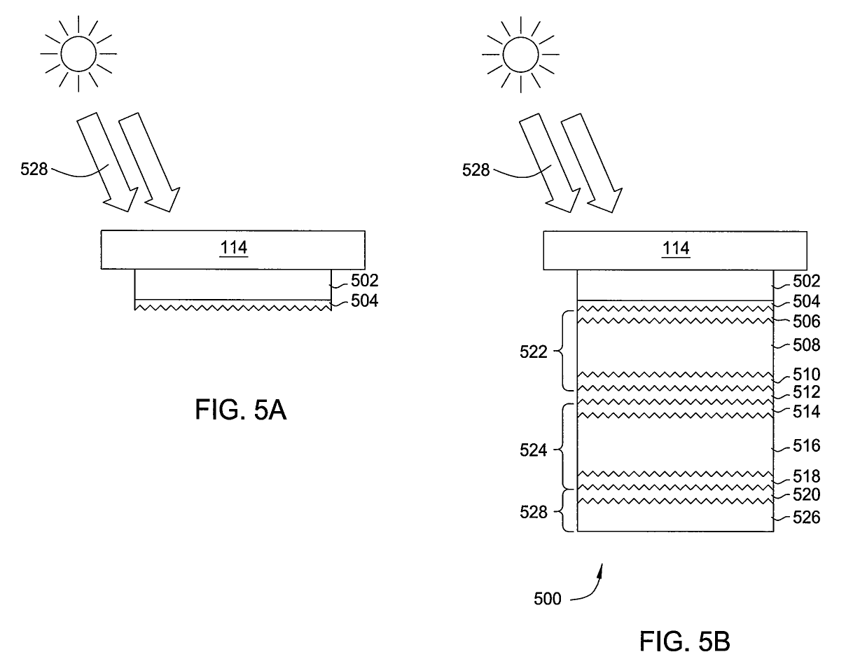

FIG. 4 depicts a process flow diagram illustrating another embodiment of a process 400 for forming a transparent conductive layer on a substrate. FIGS. 5A-B depicts cross sectional views of a tandem type PV solar cell that may be fabricated using the process 400. The process 400 forms a dual transparent conductive layer having high surface roughness as well as high film light transmission for high light conversion efficiency. The process 400 begins at step 402 by providing a substrate 114 in a sputter process chamber for deposition a transparent conductive layer on the substrate. In one embodiment, the transparent conductive layers 502, 504 may be deposited as the transparent conductive layer 202 on the substrate 114. In another embodiment, the transparent conductive layers 502, 504 may be deposited as the transparent conductive layer on the photoelectric conversion unit 214 as the back reflector 216. The substrate material may be similar to the substrate 114 as discussed above.

At step 404, the first transparent conductive layer 502 is disposed on the substrate 114, and subsequently, at step 406, the second transparent conductive layer 504, is deposited over the first transparent conductive layer 502, as depicted in FIG. 5A. In one embodiment, the first transparent conductive layer 502 may be deposited by any available conventional techniques. The first transparent conductive layer 502 may have a similar dopant concentration to the second transparent conductive layer 504. Alternatively, the first transparent conductive layer 502 may be a zinc oxide layer having aluminum dopant concentration between about 0.25 percent weight by percent and about 3 percent weight by percent. The second transparent conductive layer 504 may be deposited by the process 300 described above with referenced to FIG. 3. As the second transparent conductive layer 504 may be selected to have desired dopants formed therein, the second transparent conductive layer 504 formed on the first transparent conductive layer 502 may have a high surface roughness, thereby enhancing light trapping capability in the transparent conductive film to improve light scattering. In one embodiment, the second transparent conductive layer 504 may have a boron oxide or titanium oxide dopant concentration between about 0.25 percent by weight and about 5 percent by weight in a ZnO based layer. The second transparent conductive layer 504 is desired to have a surface roughness greater than 30 nm, such as between about 30 nm and about 80 nm.

After the dual transparent conductive layers 502, 504 have been formed on the substrate 114, a similar structure of the PV solar cell 522, 524 may be formed on thereover, as depicted in FIG. 5B. It is contemplated that the dual transparent conductive layer structure may be utilized in any form of PV solar cell, including a signal junction cell depicted in FIG. 3 or a tandem type PV solar cell depicted in FIG. 5B.

By utilizing the dual layer structure of the transparent conductive layers 502, 504, the surface roughness can be efficiently controlled. One step depositing a single transparent conductive layer may also create a transparent conductive layer having desired surface roughness. However, as the transparent conductive layer thickness increases, the roughness of the film surface may not be as easily controlled. The surface topography may be changed with the increase of the film thickness during deposition. Accordingly, by utilizing the dual layer structure of the transparent conductive layers 502, 504, the first transparent conductive layer 502 may provide a sufficient thickness required for the structure and the formation of the second transparent conductive layer 504 may provide required film roughness to enhance light trapping and scattering. Accordingly, by efficiently controlling the thickness of the second transparent conductive layer 504, the surface topography (e.g., roughness) may also be efficiently controlled in a desired range to maximize the light trapping efficiency. In one embodiment, the thickness of the first transparent conductive layer 502 is between less than about 7000 Å and the thickness of the second transparent conductive layer 504 is between about 5000 Å and about 10000 Å.

The exemplary embodiment depicted in FIG. 5B is a tandem type PV solar cell 500 having a similar structure of the PV solar cell 200, as depicted in FIG. 2, formed thereover. A first photoelectric conversion unit 422 is formed on the dual transparent conductive layers 502, 504. The first photoelectric conversion unit 522 may be pc-Si based, poly-silicon or amorphous based photoelectric conversion unit as the photoelectric conversion unit 214 described in FIG. 2. An intermediate layer 510 may be formed between the first photoelectric conversion unit 522 and a second photoelectric conversion unit 524. The intermediate layer 512 may be a transparent conductive layer sputter deposited by the process 300 described above. Alternatively, the intermediate layer 512 may be a SiO, SiC, SiON, or other suitable doped silicon alloy layer. The combination of the first underlying conversion unit 522 and the second photoelectric conversion unit 524 as depicted in FIG. 5B increases the overall photoelectric conversion efficiency.

The second photoelectric conversion unit 524 may be an pc-Si based, poly-silicon or amorphous based and have an pc-Si film as the i-type semiconductor layer 516 sandwiched between a p-type semiconductor layer 514 and a n-type semiconductor layer 518. A back reflector 528 is disposed on the second photoelectric conversion unit 524. The back reflector 528 may be similar to back reflector 216 as described with reference to FIG. 2. The back reflector 528 may comprise a conductive layer 526 formed on a top transparent conductive layer 520. The materials of the conductive layer 526 and the transparent conductive layer 520 may be similar to the conductive layer 212 and transparent conductive layer 210 as described with reference to FIG. 2.

Thus, methods for sputtering depositing a transparent conductive layer with high surface roughness are provided. The method advantageously produces a transparent conductive layer having desired optical film properties and surface roughness across its thickness. In this manner, the transparent conductive layers efficiently increase the photoelectric conversion efficiency and device performance of the PV solar cell as compared to transparent conductive films deposited using conventional methods.

While the foregoing is directed to embodiments of the present invention, other and further embodiments of the invention may be devised without departing from the basic scope thereof, and the scope thereof is determined by the claims that follow.

What is claimed is:

1. A method of sputter depositing a transparent conductive layer, comprising:
supplying a gas mixture into a processing chamber;
sputtering source material from a target disposed in the processing chamber, wherein the target comprises dopants doped into a base material, wherein the dopants are selected from a group consisting of boron containing materials, titanium containing materials, tantalum containing materials, tungsten containing materials, alloys thereof, or combinations thereof; and
reacting the sputtered material with the gas mixture to deposit a transparent conductive layer on a substrate disposed in the processing chamber.

2. The method of claim 1, wherein the transparent conductive layer has a surface roughness greater than about 30 nm.

3. The method of claim 1, wherein the base material is a zinc containing material.

4. The method of claim 3, wherein the base material is zinc oxide.

5. The method of claim 1, wherein the dopant doped into the base material has a dopant concentration less than 10 percent by weight.

6. The method of claim 1, wherein the dopants present in the transparent conductive layer is boron oxide or titanium oxide.

7. The method of claim 1, wherein the gas mixture includes at least one of O₂, H₂ and Ar.

8. The method of claim 1, wherein sputtering source material from the target further comprises:
applying a RF power between about 1000 Watts and about 60000 Watts to the target.

9. The method of claim 1, wherein a photoelectric conversion unit is disposed over the transparent conductive layer on the substrate.

10. A method of forming a transparent conductive layer, comprising:
providing a substrate in a processing chamber;
forming a first transparent conductive layer on the substrate; and
forming a second transparent conductive layer on the first transparent conductive layer, wherein the second transparent conductive layer comprising dopants doped into a base material, wherein the dopants is selected from a group consisting of boron containing materials, titanium containing materials, tantalum containing materials, tungsten containing materials, alloys thereof, or combinations thereof.

11. The method of claim 10, wherein the second transparent conductive layer has a surface roughness greater than about 30 nm.

12. The method of claim 10, wherein the first transparent conductive layer has a thickness less than about 7000 Å and the second transparent conductive layer has a thickness between about 5000 Å and about 10000 Å.

13. The method of claim 10, wherein the dopant doped into the base material of the second transparent conductive layer has a dopant concentration less than 10 percent by weight.

14. The method of claim 10, wherein the dopant is boron oxide or titanium oxide.

15. The method of claim 14, wherein the base material is a zinc containing material.

16. The method of claim 10, wherein the dopants formed in the second transparent conductive layer have grain sizes substantially smaller or lager than the grain sizes of the base material.

17. The method of claim 10, wherein forming the first and the second transparent conductive layers further comprise:
forming the first and the second transparent conductive layers by a sputter process.

18. A film stack for a PV solar cell, comprising:
a substrate having a first transparent conductive layer disposed thereon; and
a second transparent conductive layer deposited on the first transparent conductive layer, wherein the second transparent conductive layer, the second transparent conductive layer having a surface roughness greater than about 30 nm, the second transparent conductive layer having dopants doped into a base material, wherein the dopants are selected from a group consisting of boron containing materials, titanium containing materials, tantalum containing materials, tungsten containing materials, alloys thereof, or combinations thereof.

19. The film stack of claim 18, wherein dopants formed in the second transparent conductive layer have a concentration less than about 10 percent by weight.

20. The film stack of claim 18, wherein dopants formed in the second transparent conductive layer have grain sizes substantially smaller or lager than the grain sizes of the base material.

21. The film stack of claim 18, wherein the dopant is boron oxide or titanium oxide.

22. The film stack of claim 21, wherein the base material is zinc oxide.

23. The film stack of claim 18, further comprising:
a first photoelectric conversion unit formed over the second transparent conductive layer.

24. The film stack of claim 23, further comprising:
a second photoelectric conversion unit formed over the first photoelectric conversion unit.
